(19) United States
(12) Patent Application Publication
(10) Pub. No.: US 2014/0048135 A1
(43) Pub. Date: Feb. 20, 2014

(54) METHOD AND APPARATUS FOR FORMING AN IMAGE HAVING A UNIFORM FLUX DENSITY ON A SOLAR CELL

(71) Applicant: BRIGHTLEAF TECHNOLOGIES, INC., Montrose, CO (US)

(72) Inventor: James E. Vander Mey, Dunnellon, FL (US)

(73) Assignee: brightLeaf Technologies, Inc., Montrose, CO (US)

(21) Appl. No.: 13/669,569

(22) Filed: Nov. 6, 2012

Related U.S. Application Data
(60) Provisional application No. 61/684,460, filed on Aug. 17, 2012.

(51) Int. Cl. H01L 31/0232

(52) U.S. Cl. CPC H01L 31/02325
USPC 136/259

(57) ABSTRACT

Concentrated light from a solar collector in a CPV system is conditioned with a final optic element (FOE) that projects the light onto an adjacent photovoltaic cell where it is converted into electricity. The FOE is strategically configured and positioned to control the image formation on the solar cell. Use of this FOE in a CPV system design has large off axis acceptance angles (eg 1.4 degrees at 1000+ suns) and large CAP (eg 0.82). Light through the FOE is deterministically conditioned to provide uniform intensity distribution on the cell over the entire operating range of off axis conditions. Image control provided by the FOE also limits incident angle growth of the image on the solar cell allowing implementation of more compact smaller “f” ratio CPV systems.

### BACKGROUND

1. Field of Invention

The invention relates generally to maximizing output from a concentrated photovoltaic (CPV) system. More specifically, the invention relates generally to a method and system of using a final optic element (FOE) to condition a concentrated image from either a reflective or refractive optical element acting as the solar energy collector or primary optical element (POE).

2. Description of Prior Art

Converting solar energy into electricity is often accomplished by directing the solar energy onto one or more photovoltaic cells. The photovoltaic cells are typically made from semiconductors, that can absorb energy from photons from the solar energy, and in turn generate electron flow within the cell. A solar panel is a group of these cells that are electrically connected and packaged so an array of panels can be produced; which is typically referred to as a flat panel system. An array of panels used together is typically referred to as a solar flat panel photovoltaic (PV) system. Solar systems are typically positioned so that on the average they receive rays of light directly from the sun.

Some solar energy systems employ solar collectors that concentrate and focus solar radiation onto a solar cell; which are referred to as Concentrated Photo Voltaic (CPV) systems. These solar energy collectors are called the primary optical element (POE) in a CPV system and are generally either a reflective type, that typically uses high reflectivity parabolic mirrors, or a refractive type, that typically uses Fresnel lenses. Receivers usually include an optic element just before the solar cell to collect and condition the concentrated light onto a photovoltaic cell that typically has a higher performance than cells used in flat panel systems. That optic is called the final optic element (FOE).

In most cases the FOE is also the secondary optic element, thus is often commonly referred to as the SOE, though the FOE may not be the second optic element. That is because sometimes there is an intermediate optic element between the POE and the FOE such as in a cassagrain-type concentration system. A cassagrain CPV system often has a parabolic mirror reflector as the POE and a hyperbolic mirror reflector as the SOE. The hyperbolic secondary optic condenses the overall depth of the system by reversing the direction of the light before it arrives at the FOE. Shortcut annotation for the type of optical system used is to catentate the optic elements as reflective (X) or refractive (R). Generally accepted designations for: (1) a system with a reflective POE and a refractive SOE is a XR system; (2) a cassagrain-type system is an XXR system; and (3) a Fresnel system is an RR system.

The amount of concentration achieved by a CPV system is typically measured in non-dimensional units called “suns”, which is the geometric ratio of a POE collection area to the active solar cell area. Concentrating or magnifying sunlight can produce 1000 times or more intense light flux onto a CPV receiver than that of a flat panel system. CPV system performance depends on the alignment of the POE and SOE optical path with the axis of the sun's light rays. If the optical path is not aligned with the axis, some or all of the projected sun rays (image) will fall outside of the solar cell receiver element.

Acceptance angle is a criterion for specifying off axis performance in a CPV system; and is defined as the off-axis angle at which the CPV power generated at the solar cell drops to 90% of that of the perfectly coaxial on-axis power. An appropriately designed FOE can greatly increase the acceptance angle of a CPV system. The concentration level and the “f” ratio are some of the factors that can impact the acceptance angle. The “f” ratio of the CPV system is the ratio of the aperture (POE diameter) to the focal length at the focal point which is usually at or near the top surface of the FOE. For a given focal length, as the concentration factor of a CPV system increases the f ratio decreases, and the cone angle of the concentrated light enlarges due to the increased geometric ratio of the FOE.

Maximizing conversion efficiency of the light to electricity requires uniform intensity of the ray bundle light energy (sometimes called the ‘flux’) when the light impinges on the solar cell. A non-uniform flux energy at the cell compromises the effective “fill factor” of the cell; which is a measure of open circuit performance versus the performance under load. The fill factor of a solar cell is one characteristic of self-losses, and usually measured under ideal conditions. Uneven flux often generates uneven current in the cell layers, which decreases the cell's operational fill factor, to decrease the solar cell power output. Extreme uneven flux affects the reliability and longevity of the solar cell by creating hot spots that overheat and stress the cell.

Increasing angles of incident light rays eventually decreases the power converted at the solar cell. Typical solar cells have substantially uniform conversion rates for angles of incidence ranging from zero to 60 degrees or less to a line normal with a surface of the cell. However, for angles of incidence above 60 degrees, the solar energy conversion response drops off rapidly.

In some embodiments, light from the reflector is collected and delivered to the solar cell with receiver optics that condition the light, to improve the acceptance angle, promote uniform intensity under varying image conditions, and limit the angle of incidence of rays to the solar cell. One technique employed is to use a final optic that employs a statistical mixing approach where entering rays semi-randomly are mixed into a homogeneous image at the cell. Generally the focal point of the entering rays is at or near the top edge of the optic. One example of a statistical optic is a kaleidoscope homogenizer with a long truncated prism, often with a convex dome lens element at the top entry surface. This optic system operates on the principle of reflecting some of the diverging light rays by total internal reflection (TIR) off steep sidewalls multiple times to produce a mixed and diffused image onto the solar cell. Prism sidewalls for statistical optics tend to be very steep as the homogenizing depends on the mixing effect of multiple internal reflections. A consequence is that each reflection increases the incident angle away from the axis of the optic resulting in increased incident angles of the rays at the exit surface at the solar cell. Thus this type of optic can be used only with limited cone angles of the incident bundle of rays (i.e. “f” ratio of the system is high).

Another technique for directing light rays is a deterministic method where the FOE optic maps the image always in a predictable non-random way. A common deterministic type FOE optic is a convex domed lens that attempts to focus the ray bundle as an image on the cell. Simple domed lenses are low in cost due to their small size and relatively non critical optical characteristics. However, to allow room for off axis movement, the on-axis image for a domed lens requires being focused in a reduced area in the center of the cell; which creates a center hot spot that can move under off axis conditions. Further, images produced by domed lenses are distorted and can only tolerate a very modest off axis condition compared to a kaleidoscope type optic. Thus, the suitability for domed lenses is limited to lower concentration systems. Kohler integration is another example of a type of deterministic optic that has been developed, which employ multiple dome lenses. Kohler integration optics produce better flux uniformity and a better acceptance angle than a simple domed optic on axis, but still suffer from inferior flux performance off-axis.

Figures of merit for a CPV design have been developed to evaluate the performance of FOE. One figure of merit, designated ‘CAP’, measures the acceptance angle performance of a FOE relatively independently of the concentration and is a represented as:

CAP=(C_{g})^{0.5}×sin(acpt_ang) Eqn. 1

Where C_{g} is the geometric concentration ratio defined as the area of the POE collector to the active area of the solar cell, and acpt_ang is the acceptance angle. Acceptance angles and CAP are generally calculated using geometric ray tracing simulating parallel rays from the sun. In reality, the operational acceptance angle will be reduced by the fact that sun rays are not strictly parallel, but occupy a cone of approximately 0.27 degrees. This is because the sun is not a point source at infinity, but has certain diameter and distance from the earth. Other figures of merit relate to the relative intensity variation at the exit of the FOE (at the solar cell). One is the ratio of the maximum flux to the mean flux, usually at a specified off axis angle. Another is the ratio of the minimum to maximum flux.

### SUMMARY OF THE INVENTION

Provided herein is a method of and apparatus for directing light energy to a solar cell. In one example method a focused beam of light is received that has an axis and rays that diverge radially outward away from the axis after passing a focal area. Some of the diverging rays reflect from an outer periphery of the beam in a direction generally towards the axis to form an image with a uniform flux density superimposed onto the solar cell. The image is made up of reflected rays and rays that extend along a substantially straight path from the focal area. Optionally, some of the diverging rays are reflected no more than a single time. Alternatively, the method can further include refracting the beam of light, so that when the beam of light is received from a solar collector that is in an off axis position from the sun, the flux density of the image superimposed onto the solar cell remains substantially uniform. In an example, energy in the image at an off axis position of about 1.4° is about 90% of the energy of the image at an off axis position of about 0°. In one example embodiment, the method can further involve providing a prism element whose sides reflect by total internal reflection the some of the diverging rays, wherein the prism sides are disposed at an angle of about 7° to about 11° from an axis of the prism. The diverging rays can follow respective paths between the focal area and reflective sides, that when the paths are extended along straight uninterrupted lines define a projected image in a plane that is substantially parallel with the solar cell, wherein the projected image has an area about twice an area of the image on the solar cell. In one example, the rays are distinct from one another and are deterministically arranged.

Also provided herein is an example of a solar energy system that includes a solar cell and an optic made up of a truncated prism element with an inlet end, and a convex lens element adjacent the inlet end to refract the rays into a narrower concentrated beam towards an axis of the optic thus minimizing displacement of the beam of light away from the solar cell under off-axis conditions. The prism element also has an exit end disposed adjacent the solar cell, side walls that are at an angle with respect to the axis of the optic to produce TIR reflections and extend between the inlet end and exit end. When a concentrated beam of light having a focal area and made up of rays enters via the lens element, some of the rays diverge from the focal area and reflect from the side walls, and an image with a substantially uniform flux density is formed on the solar cell that is made up of the reflected rays and rays that travel along a substantially straight path from the focal area to the solar cell. In one alternate example, the prism has a substantially rectangular cross section and wherein the side walls are at angles of from about 7° to about 11° from the axis of the optic. The geometry and positioning of the optic ensure that the reflected rays can reflect no more than once from the side walls before encountering the solar cell. Further optionally included is a solar collector POE for forming the concentrated beam of light. The optic can be strategically disposed in a path of the beam of light so that the focal area is between the inlet end and exit end. In one example embodiment, further included is a circuit having an electrical load in electrical communication with the solar cell.

Also described herein is a method of forming an image on a solar cell. In this example a beam of light made up of rays that diverge from a focal area is received. A solar cell is provided in a path of some of the rays and an image is formed on the solar cell by deterministically reflecting the diverging rays that are on paths that extend outside of an outer perimeter of the solar cell and onto paths that intersect the solar cell. In one example, the beam of light is received from a solar collector that is off-axis from the sun at an acceptance angle of 1.4° where the energy in the image is at about 90% of an image formed when the solar collector is substantially on axis with the sun and the flux density is substantially uniform in density.

### BRIEF DESCRIPTION OF THE DRAWINGS

Some of the features and benefits of the present invention having been stated, others will become apparent as the description proceeds when taken in conjunction with the accompanying drawings, in which:

FIG. 1 is a schematic view of an example embodiment of a solar collector reflecting light to a solar conversion system in accordance with the present invention.

FIG. 2 is a side partial sectional view of an example embodiment of an optic with lens and prism elements included with the solar conversion system of FIG. 1 in accordance with the present invention.

FIG. 2A is a side partial sectional view of an alternate example of an optic with the lens and prism elements of FIG. 2 with additional integrated mechanical mounting detail and in accordance with the present invention.

FIGS. 3A and 3B are plan views respectively of a projected light image without and with the optic in accordance with the present invention.

FIG. 4 is an illustration of how light from an off axis solar collector is conditioned by the optic of FIG. 2 in accordance with the present invention.

FIGS. 4A and 4B illustrate an example plan view of how the rays are mapped by the example of FIG. 4.

FIG. 5 is a schematic example of an alternate embodiment of the optic of FIG. 4 without the lens element.

FIGS. 6-8 are schematic illustrations of an example of an optic receiving beams that are off axis, in accordance with the present invention.

While the invention will be described in connection with the preferred embodiments, it will be understood that it is not intended to limit the invention to that embodiment. On the contrary, it is intended to cover all alternatives, modifications, and equivalents, as may be included within the spirit and scope of the invention as defined by the appended claims.

### DETAILED DESCRIPTION OF INVENTION

The method and system of the present disclosure will now be described more fully hereinafter with reference to the accompanying drawings in which embodiments are shown. The method and system of the present disclosure may be in many different forms and should not be construed as limited to the illustrated embodiments set forth herein; rather, these embodiments are provided so that this disclosure will be thorough and complete, and will fully convey its scope to those skilled in the art. Like numbers refer to like elements throughout.

It is to be further understood that the scope of the present disclosure is not limited to the exact details of construction, operation, exact materials, or embodiments shown and described, as modifications and equivalents will be apparent to one skilled in the art. In the drawings and specification, there have been disclosed illustrative embodiments and, although specific terms are employed, they are used in a generic and descriptive sense only and not for the purpose of limitation. Accordingly, the improvements herein described are therefore to be limited only by the scope of the appended claims.

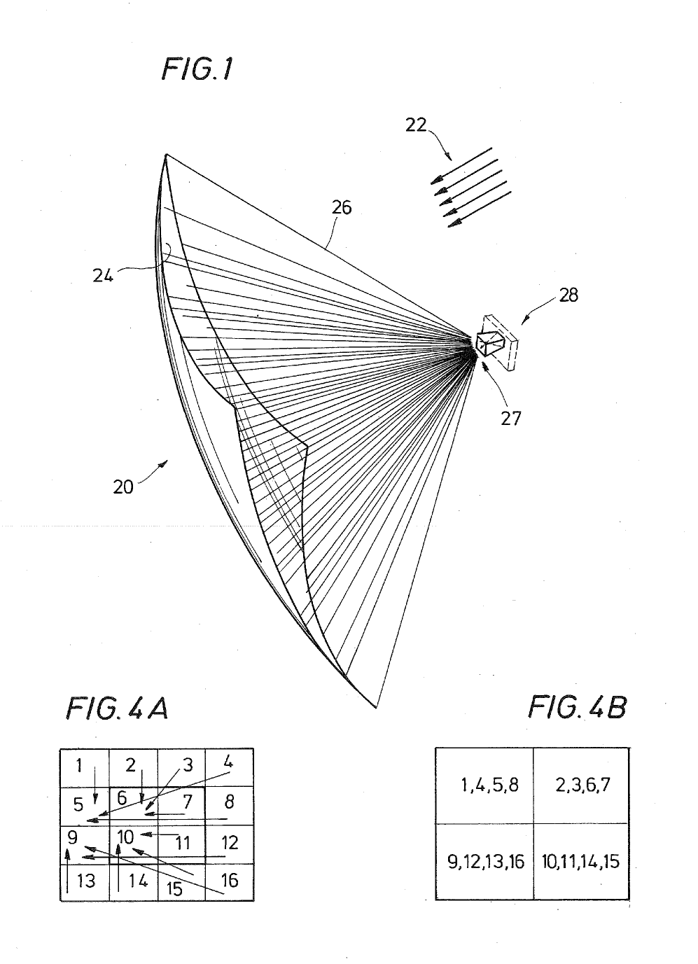

FIG. 1 is a side perspective view of one example of a solar collector 20 shown disposed in the path of solar rays 22. The collector 20, also called the primary optical element (POE), is formed from a generally planar member that is shaped and curved to define a generally concave-like side on which a reflective surface 24 is provided. The solar rays 22 contact the reflective surface 24 and form reflected rays 26 that are shown converging towards a focal area 27. Although shown as having a defined area, the focal area 27 may instead be a focal point. Examples exist where the focal area 27 has a generally rectangular or curved cross-sectional shape. A conversion system 28 is shown disposed proximate the focal area 27, and as described in more detail below, is used for converting energy in the solar rays 22 and reflected rays 26 into useful electricity.

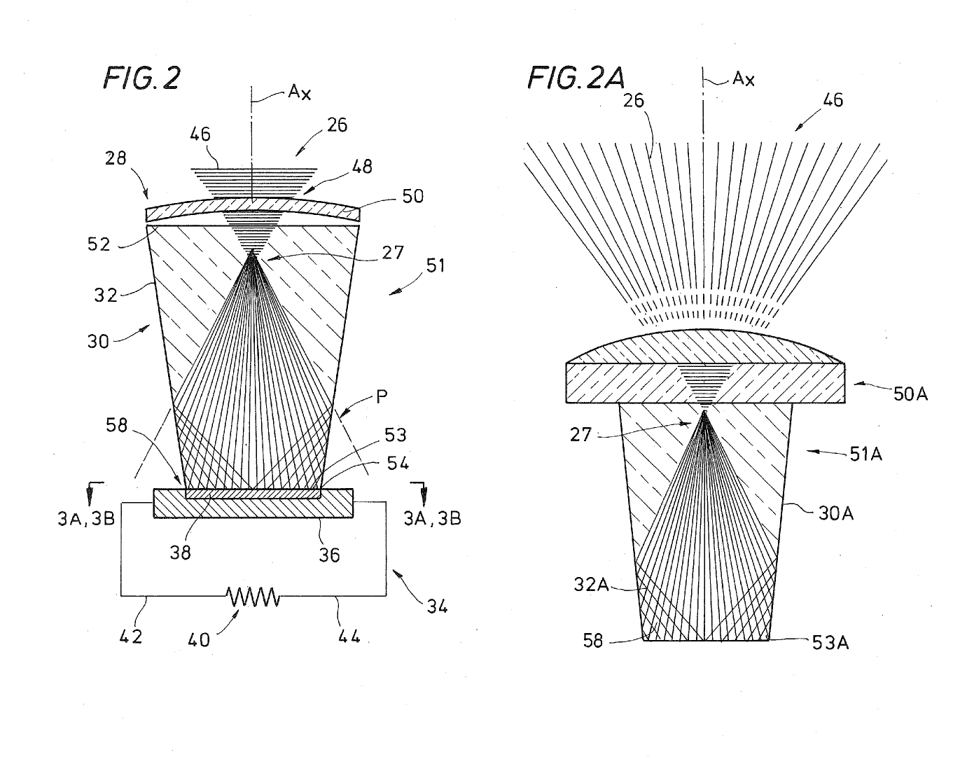

FIG. 2 provides an example embodiment of the conversion system 28 in more detail and in a side schematic view. In this example, the optic 51 is made up of a convex lens element 50 disposed adjacent to a truncated prism 30 having side walls 32 at a shallow angle to the axis that produces incoming ray reflection off the side walls by TIR. In an example embodiment, the optic 51 is the final optic element (FOE). The rays 26 of FIG. 2 from the solar collector 20 (FIG. 1) are represented as a converging beam of light 46. In the example of FIG. 2, the lens 50 is illustrated adjacent an inlet end 52 of the prism 30 and refracts the beam 46 towards the prism 30 axis as the beam 46 enters the inlet end 52. Further in the example of FIG. 2, the focal area 27 is within the prism 30 downstream of the inlet end 52. Past the focal area 27, the reflected rays 26 begin to diverge radially outward from an axis A_{X} of the beam 46. Some of the diverging rays follow a straight path onto an upper surface of the solar cell 38. However, some of the diverging rays 26 diverge far enough radially outward that they intersect one of the side walls 32 of the prism 30. The configuration of the side walls 32 and length of the prism 30 is strategically established so that the rays 26 reflect from the side walls 32 and radially inward towards the axis A_{X}. The reflected and non-reflected rays 26 leave the prism 30 thru an exit end 53. A circuit 34 is shown adjacent the prism 30, where the circuit 34 includes a receiver 36 in which a solar cell 38 is embedded on an upper surface of the receiver 36. The example of the circuit 34 of FIG. 2 also includes an electrical load 40 in electrical communication with the solar cell 38 via electrically conducting leads 42, 44.

In an alternate example, shown in side sectional view in FIG. 2A is an example of an optic 51A that includes a convex lens 50A upper surface and extension flange shown disposed on a prism 30A. The extension flange of FIG. 2A has no optical effect on the performance of the optic 51A when properly placed, but can provide manufacturing and assembly locating attachment points. In this example a substantially on-axis beam 46 contacts the convex lens 50A and is directed into the prism 30A. Similar to the example of FIG. 2, a portion of the rays 26 are direct and contact the exit 53A of the prism 30A without reflecting from the sides 32A, while a portion of the rays 26 that make up the rest of the beam 46 reflect from the sidewalls 32A and overlay onto the image 58 formed adjacent the exit 53A. Further in the embodiment of FIG. 2A, a focal area 27 of the beam is adjacent to an interface between the inlet 52A to the prism 30A and bottom surface of the lens 50A.

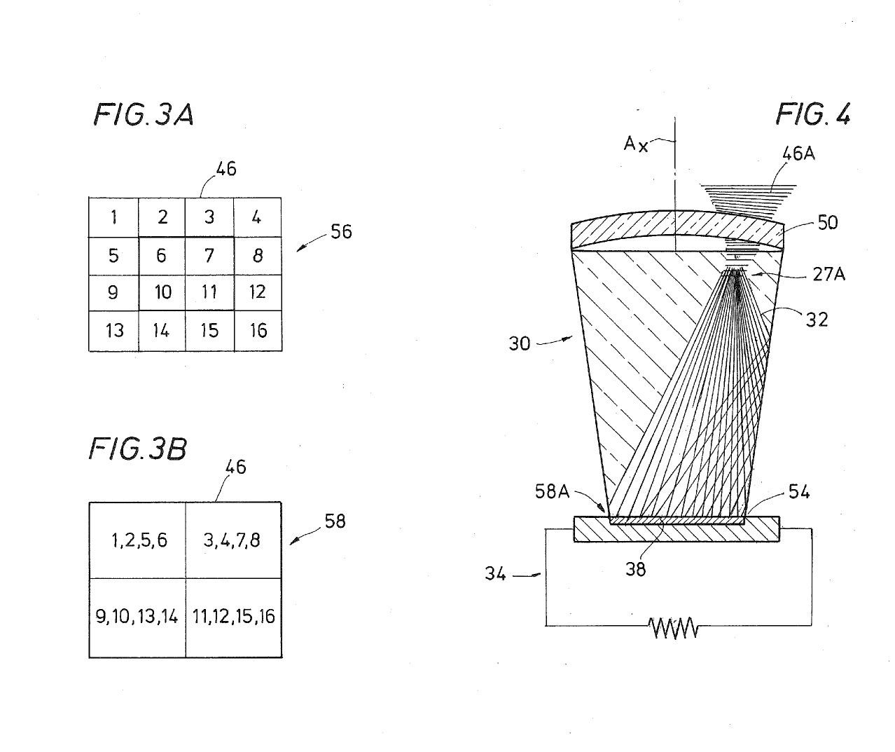

A projected path of the diverging rays 26 is illustrated by dashed line P shown extending downward and radially outward from the outer surface of the side walls 32. FIG. 3A is a plan view representing how a projected image 56 might appear in a plane coincident with an upper surface of the solar cell 38. The projected image 56 is partitioned into multiple blocks to illustrate the spatial portions of the projected image 56. In the example of FIG. 3A, the partitions number from 1 to 16. Further shown in the example of FIG. 3A is that blocks numbered 6, 7, 10, and 11 represent the area coincident with the solar cell 38. Thus by reflecting the diverging rays radially inward towards the axis A_{X} the rays making up portions 1 through 5, 8, 9, and 12 through 16 are reflected into the areas represented by sections 6, 7, 10, and 11. Without reflecting off side walls 32, the rays making up the rays making up portions 1 through 5, 8, 9, and 12 through 16 would not contact the solar cell 38.

In one example, the rays 26 are deterministically mapped by the configuration of the prism 30 to form a processed image 58 shown cast onto the solar cell 38 (FIG. 2). In the illustrated example, the image 58 has a predictable shape and density; and the flux density of the example image 58 is substantially homogenous. In one example, the deterministically mapped rays 26 reflect from the side walls 32 a single time and form the image 58 without mixing with other rays 26. Unlike a homogenizer that allows for multiple reflections of light rays therein, the prism 30 limits the light rays to a single reflection and thereby controls the angle of incidence at which the rays 26 contact the solar cell 38.

In FIG. 3B, an example is illustrated of how the straight path rays and reflected rays combine to form the processed image 58. More specifically, the example of FIG. 3B illustrates where in the processed image 58 are located the portions 1-16 of the projected image 56. One section of the processed image 58 has portions 1, 2, 5, 6 of the projected image 56; an adjacent portion of the processed image 58 has sections 3, 4, 7, 8 of the projected image 56; a third section of the processed image 58 includes portions 9, 10, 13, 14 of the projected image 56; and a fourth section of the processed image 58 of FIG. 3B contains portions 11, 12, 15, 16 of the projected image 56 of FIG. 3A. For the purposes of discussion herein, it is considered that the peripheral portions, i.e., 1 through 5, 8, 9, and 12 through 16, are folded into those sections in the inner portion of the projected image 56.

In one example of operation, the prism 30 and lens 50 are positioned such that a direct portion of the beam 46 passing through the lens 50 intersects the solar cell 38 and an indirect portion of the beam 46 passing through the lens 50 reflects a single time from the sides of the prism by TIR and is precisely superimposed onto the solar cell 38. In an example of deterministic mapping, the projected image 56 has lateral dimensions that are about twice the lateral dimensions of the solar cell 38 and has an area about four times the area of the solar cell 38. In an alternate example, the angle of the sidewalls 32 with the axis A_{X} is adjusted to adjust the size and/or area of the image 58. The maximum angle between the sidewalls 32 and axis A_{X} may be set by the acceptable incident angles to the solar cell 38. In an example embodiment, to optimize total flux of light energy cast onto the solar cell 58, the beam 46 received by optic 51 is substantially square and has a substantially homogenous flux density. In examples where the beam 46 is not square, sidewalls 32 in the prism 30 may lie at differing angles with respect to the axis AX, as the rays 26 entering the prism 30 from the lens 50 may have different angles depending on the dimension and/or shape of the lens 50.

In an alternate embodiment, FIG. 4 illustrates an optic 51 and circuit 34 in use wherein the associated beam 46A results from an off-axis condition of the collector 20 (FIG. 1). The off axis condition can be result of misalignment due to manufacturing or because of tracking errors. For the purposes of discussion herein, off-axis refers to a situation when the collector 20 is offset from the source of the solar rays 22, i.e., the sun, thereby producing a distorted image and forming a beam 46A having a shape different from the beam 46 of FIG. 2. In one example, the beam 46 of FIG. 2 represents an on-axis situation. Still referring to FIG. 4, the beam 46A is shown offset from the axis A_{X} of the prism 30 and entering the prism 30 on one side of the axis A_{X}. In this example, the indirect portion of the beam 46 moves in the opposite but equal direction of the direct portion of the beam 46. An advantage of using the optic 51 having the convex lens 50 is illustrated wherein the rays 26A making up the beam 46A are refracted by the lens 50 to a narrower beam shifted toward an axis A_{P} of the prism 30.

FIGS. 4A and 4B illustrate an example plan view of how the rays 26 are mapped by the example of FIG. 4. In this example, rays 26 (FIG. 2) that would land in portions 1-4, 7, 8, 11, 12, and 13-16 of the projected image 56 instead are mapped into one of portions 5, 6, 9, or 10. More specifically, beams 26 projected towards portions 1, 4, and 8 map to and overlay on portion 5, beams 26 projected towards portions 2, 3, and 7 map to and overlay on portion 7, beams 26 projected towards portions 11, 14, and 15 map to and overlay on portion 10, and beams 26 projected towards portions 12, 13, and 16 map to and overlay on portion 9. Because of the overlay of the beams 26, the overall intensity is maintained even when at the limit of normal operation. In one example, refracting the beam 46A with the lens 50 enables deterministic mapping of the rays 26 in the prism 30. Thus an image 58A (FIG. 4) is formed on an upper surface 54 of the solar cell 38 that has substantially the same uniform flux density as the image 58 of FIG. 2. As indicated above, the image 58 of FIG. 2 was generated using an on-axis collector. Additionally, by implementation of the optic 51 off-axis situations of up to 1.2 degrees may still produce an image having up to 98% of the energy of images produced when a solar collector is fully on-axis with the sun. In another example, off-axis configurations of up to about 1.4% can produce a corresponding image on the solar cell having energy of up to about 90% of the energy produced from an on-axis situation. Moreover, even in these off-axis situations of up to 1.4 degrees, a ratio of the maximum to mean flux density at any one point on the image on the solar cell 38 can be limited to about 1.3 or less. Thus, the use of the optic 51 can avoid high flux density conditions that can damage the solar cell.

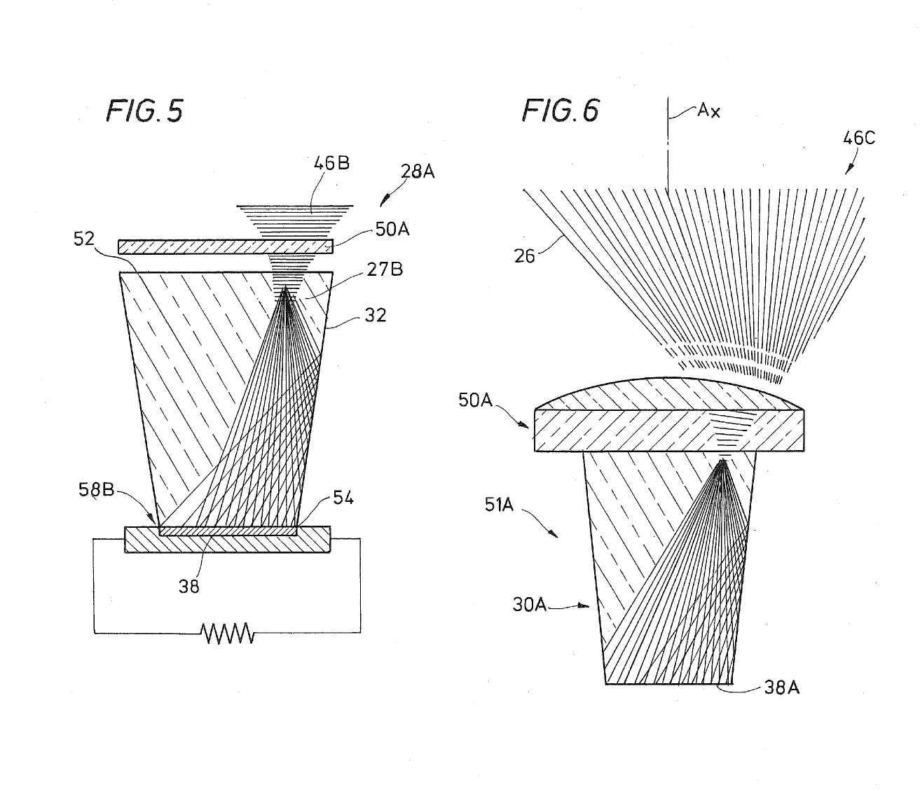

For the purposes of contrast and illustration, an alternate example of the optic 51 is shown in FIG. 5 wherein lens element 50A on an inlet end 52 of the prism 30 is provided that is substantially planar, not convex, and not curved. In this example, the beam 46B is also produced from an off-axis situation but as can be seen, the beam 46B has a larger focal area 27B than the focal area 27A of FIG. 4. As such, when the diverging rays reflect from the side walls 32 the resulting image 58B on the solar cell 38 can be seen to have higher densities in one portion of the solar cell 38 than others and more limited acceptance angles.

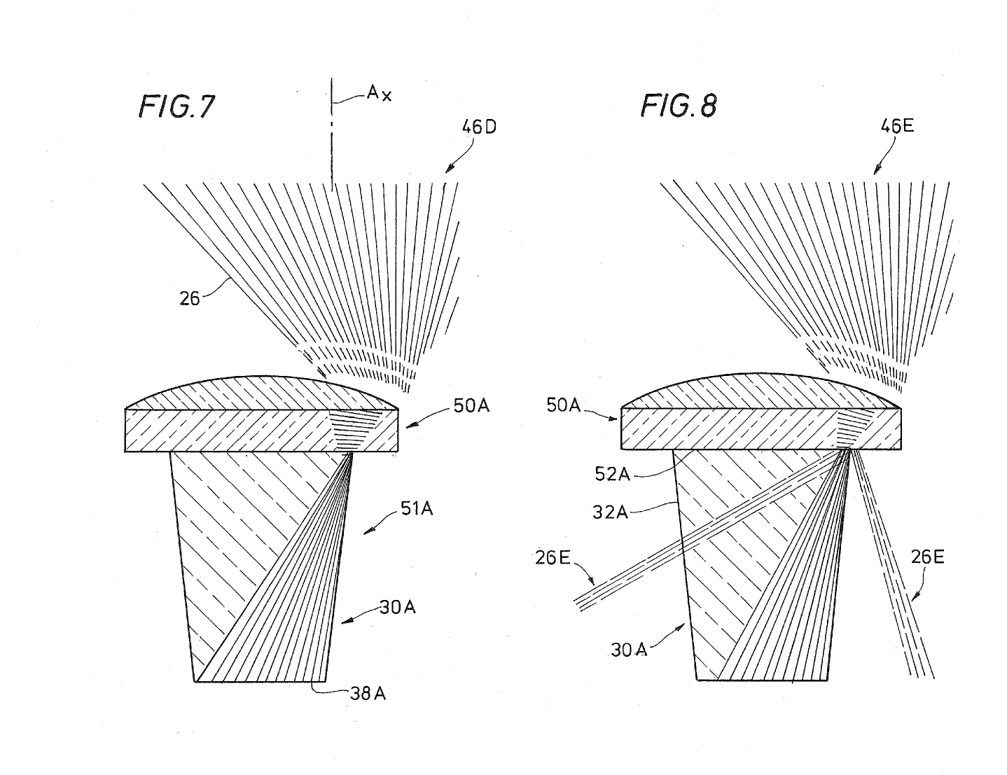

FIGS. 6 and 7 schematically illustrate an example of beams 46C, 46D offset from axis A_{X}. In one example beam 46C is offset at about 0.7 degrees from the axis A_{X} and beam 46D is offset at about 1.2 degrees from the axis A_{X}. Beams 46C, 46D contact a curved surface of lens 50A shown mounted on an upper end of prism 30A, where the prism 30A has an exit directed to solar cell 38A. In this example, angled beams 46C, 46D cause the direct image to migrate to an edge of the cell 38A. The example of the lens 50A focuses the beams 46C, 46D so that rays 26 in the beams 46C, 46D that are at a maximum angle to axis A_{X}, reflect to contact the edge of the cell 38A where the direct image is migrating.

Referring now to FIG. 8, shown is an example of image mapping at an acceptance angle that correlates to about 90 percent energy capture. In one example the acceptance angle is at its maximum value. Also shown are lost energy rays 26E that either by pass the inlet 52A to the prism 30A or reflect outside of the prism 30A and through the sidewalls 32A.

Representative figures of merits for various types of FOE optics are shown in Table 1. More specifically, optic #1 is a commercial kaleidoscope, optic #2 is a commercial dome, optic #3 is an advance Kohler free form dome, and optic #4 is an example of an optic of the present disclosure. Note that a higher CAP and lower flux ratios are desired, and that good figures of merit become harder to achieve with higher C_{g} values. In one example, the optic element described herein has a height and thus volume that is one-half to one-third of a typical kaleidoscope homogenizer optic, thus reducing the cost of materials of the optic.

TABLE 1

| | | | Peak vs. | | | |
|---|---|---|---|---|---|---|
| | | | mean | Peak vs. min | Peak vs. mean | |
| Optic | Type | CAP | flux/angle | flux/angle | Flux/max design | C_{g} |
| 1 | Statistical | .68 | | 1.4/.5 deg | Unspecified (high) | 800x |
| 2 | Deterministic | .47 | | 2.0/.5 deg | Unspecified (very high) | 800x |
| 3 | Deterministic | .70 | 1.7/.7 deg | 2.8/.7 deg | Unspecified (very high) | 804x |
| 4 | Deterministic | .82 | 1.1/.7 deg | 1.4/.5 deg | 1.3/1.4 deg | 1064x |

In addition to the superior acceptance angle and increased uniform field illumination, the deterministic final optic element (FOE) described herein has a faster “f” ratio with limited incident angles to the solar cell. The method and apparatus of the present disclosure improves solar cell electrical energy conversion in the solar system, enhances reliability of the solar cell, allows for greater tolerances in manufacturing of other components of the solar system, and reduces tracking accuracy requirements. With increasing off-axis angle of the present method and apparatus, the flux variation remains nearly constant across the operating range; unlike known designs that have much higher flux intensities as the angle increase. In addition, the optic element herein has a height and thus volume that is one-half to one-third of a typical kaleidoscope homogenizer optic; thus reducing the cost of materials of the optic. Another benefit realized by an example of the optic of the present disclosure is that smaller “f” ratios (focal length to POE aperture) can be used to eliminate the need for more expensive compound cassegrain type reflector systems requiring a secondary mirror to minimize depth of the CPV system between POE and FOE. This is due to the limit of one reflection per sun ray per side wall of the optic in the method described resulting in wider acceptable cone of input rays for the same output incident angles at the solar cell versus other multiple ray reflection optics.

The present invention described herein, therefore, is well adapted to carry out the objects and attain the ends and advantages mentioned, as well as others inherent therein. While a presently preferred embodiment of the invention has been given for purposes of disclosure, numerous changes exist in the details of procedures for accomplishing the desired results. These and other similar modifications will readily suggest themselves to those skilled in the art, and are intended to be encompassed within the spirit of the present invention disclosed herein and the scope of the appended claims.

What is claimed is:

1. A method of directing light energy to a solar cell comprising:
receiving a beam of light having an axis and rays that past a focal area diverge radially outward away from the axis; and
refracting the beam of light, so that when the beam of light is received from a solar collector that in an off axis position from the sun rays the beam is constrained towards the solar cell; and
reflecting some of the diverging rays on an outer periphery of the beam in a direction generally towards the axis to form an image with a uniform flux density superimposed onto the solar cell and that is made up of reflected rays and rays that extend along a substantially straight path from the focal area.

2. The method of claim 1, wherein the some of the diverging rays are reflected no more than a single time.

3. The method of claim 1, where the flux density of the image superimposed onto the solar cell remains substantially uniform.

4. The method of claim 3, wherein energy in the image at an off axis position of about 1.4° is about 90% of the energy of the image at an off axis position of about 0°.

5. The method of claim 1, further comprising providing a prism having sides for reflecting the some of the diverging rays, wherein the sides are disposed at an angle of about 7° to about 11° from an axis of the prism.

6. The method of claim 5, wherein the diverging rays follow respective paths between the focal area and reflective sides, that when the paths are extended along straight uninterrupted lines define a projected image in a plane that is substantially parallel with the solar cell, wherein the projected image has an area about twice an area of the image on the solar cell.

7. The method of claim 1, wherein the rays are distinct from one another and are deterministically arranged.

8. A solar energy system comprising:
a solar cell; and
an optic with a convex lens adjacent to a truncated prism having an axis, an inlet end, an exit end disposed adjacent the solar cell, side walls that are at an angle with respect to the axis that allow total internal reflection of the rays and extend between the inlet end and exit end, so that when a concentrated beam of light having a focal area and made up of rays enters the inlet end, and some of the rays diverge from the focal area and reflect from the side walls, an image with a substantially uniform flux density is formed on the solar cell that is made up of the reflected rays and rays that travel along a substantially straight path from the focal area to the solar cell.

9. The solar energy system of claim 8, wherein the prism has a substantially rectangular cross section and wherein the side walls are at angles of from about 7° to about 11° from the axis of the optic.

10. The solar energy system of claim 8, wherein the reflected rays reflect no more than once from the side walls.

11. The solar energy system of claim 8, further comprising a solar collector for forming the concentrated beam of light. x

12. The solar energy system of claim 11, wherein the optic is strategically disposed in a path of the beam of light so that the focal area is between the inlet end and exit end.

13. The solar energy system of claim 8, further comprising a circuit comprising an electrical load in electrical communication with the solar cell.

14. A method of forming an image on a solar cell comprising:
receiving a beam of light comprising rays that diverge from a focal area;
providing a solar cell that is in a path of some of the rays; and
forming an image on the solar cell by deterministically reflecting the diverging rays that are on paths that extend outside of an outer perimeter of the solar cell and onto paths that intersect the solar cell.

15. The method of claim 14, wherein the image has a substantially uniform flux density.
